(19) United States
(12) Patent Application Publication
(10) Pub. No.: US 2008/0272468 A1
(43) Pub. Date: Nov. 6, 2008

(54) GROUNDED SHIELD FOR BLOCKING ELECTROMAGNETIC INTERFERENCE IN AN INTEGRATED CIRCUIT PACKAGE

(76) Inventors: Farshad Ghaghahi, Saratoga, CA (US); Shahram Nikoukary, Santa Clara, CA (US); Halford Kokichi Tome, Milpitas, CA (US)

Correspondence Address: LSI Logic Corporation;Corporate Legal Department, Intellectual Property Services Group, M/S D-106, 1621 Barber Lane, Milpitas, CA, 95035, US

(21) Appl. No.: 11/743,162

(22) Filed: May 2, 2007

(51) Int. Cl. H05K 9/00; H01L 21/00; H01L 23/552

(52) U.S. Cl. 257/659; 438/122; 257/E23.114; 257/E21.001

(57) ABSTRACT

An integrated circuit package for blocking electromagnetic interference includes a top layer formed in a package substrate. A first plurality of via groups is formed in the top layer surrounding an area on the top layer for an integrated circuit die. At least one lower layer is formed in the package substrate. A lower via group is formed in the lower layer below each of the first plurality of via groups, respectively. An electrical connection is formed in the lower layer between each lower via group and the first plurality of via groups, respectively. A ground connection is formed in the integrated circuit package for each lower via group to connect each lower via group to an electrical ground to block electromagnetic interference.

### BACKGROUND OF THE INVENTION

1. Field of the Invention

The present invention is directed to the design and manufacture of integrated circuits. More specifically, but without limitation thereto, the present invention is directed to a grounded shield.

2. Description of Related Art

In previous techniques for shielding an integrated circuit package, electrically conductive clips are attached on each side of the integrated circuit package between the electrically conductive metal lid or heat spreader on top of the integrated circuit package and a ground plane on a printed circuit board. The grounded conductors on the top and the sides of the integrated circuit package block electromagnetic interference (EMI) from entering or radiating from the integrated circuit package.

### SUMMARY OF THE INVENTION

In one embodiment, an integrated circuit package for blocking electromagnetic interference includes a top layer formed in a package substrate. A first plurality of via groups is formed in the top layer surrounding an area on the top layer for an integrated circuit die. At least one lower layer is formed in the package substrate. A lower via group is formed in the lower layer below each of the first plurality of via groups, respectively. An electrical connection is formed in the lower layer between each lower via group and the first plurality of via groups, respectively. A ground connection is formed in the integrated circuit package for each lower via group to connect each lower via group to an electrical ground to block electromagnetic interference.

In another embodiment, a method of making an integrated circuit package includes steps of forming a top layer in a package substrate. A first plurality of via groups is formed in the top layer surrounding an area on the top layer for an integrated circuit die. At least one lower layer is formed in the package substrate. A lower via group is formed in the lower layer below each of the first plurality of via groups, respectively. An electrical connection is formed in the lower layer between each lower via group and the first plurality of via groups, respectively. A ground connection is formed in the integrated circuit package for each lower via group to connect each lower via group to an electrical ground to block electromagnetic interference.

### BRIEF DESCRIPTION OF THE DRAWINGS

The present invention is illustrated by way of example and not limitation in the accompanying figures, in which like references indicate similar elements throughout the several views of the drawings, and in which:

FIG. 1 illustrates side view of a shielded integrated circuit package of the prior art with a heat spreader;

FIG. 2 illustrates a side view of an integrated circuit package with internal side shielding;

FIG. 3 illustrates a magnified view of an integrated circuit package with a ground shield for grounding to a printed circuit board;

FIG. 4 illustrates a top view of the top layer in the package substrate of FIG. 3;

FIG. 5 illustrates a magnified view of a via group formed in the top layer of the package substrate in FIG. 4;

FIG. 6 illustrates a magnified view of a via group formed on the top layer of a ten-layer package substrate;

FIG. 7 illustrates a magnified view of connections formed in the second layer between the via group in the top layer and the via group in the third layer of the package substrate of FIG. 6;

FIG. 8 illustrates a magnified view of connections formed in the third layer between the via group in the second layer and the via group in the fourth layer of the package substrate of FIG. 7;

FIG. 9 illustrates a magnified view of connections formed in the fourth layer between the via group in the third layer and the via group in the fifth layer of the package substrate of FIG. 8;

FIG. 10 illustrates a flow chart for making the integrated circuit package of FIG. 3; and

FIG. 11 illustrates a flow chart for making an integrated circuit package with a ground shield grounded inside the integrated circuit package.

Elements in the figures are illustrated for simplicity and clarity and have not necessarily been drawn to scale. For example, the dimensions of some elements in the figures may be exaggerated relative to other elements to point out distinctive features in the illustrated embodiments of the present invention.

### DESCRIPTION OF THE ILLUSTRATED EMBODIMENTS

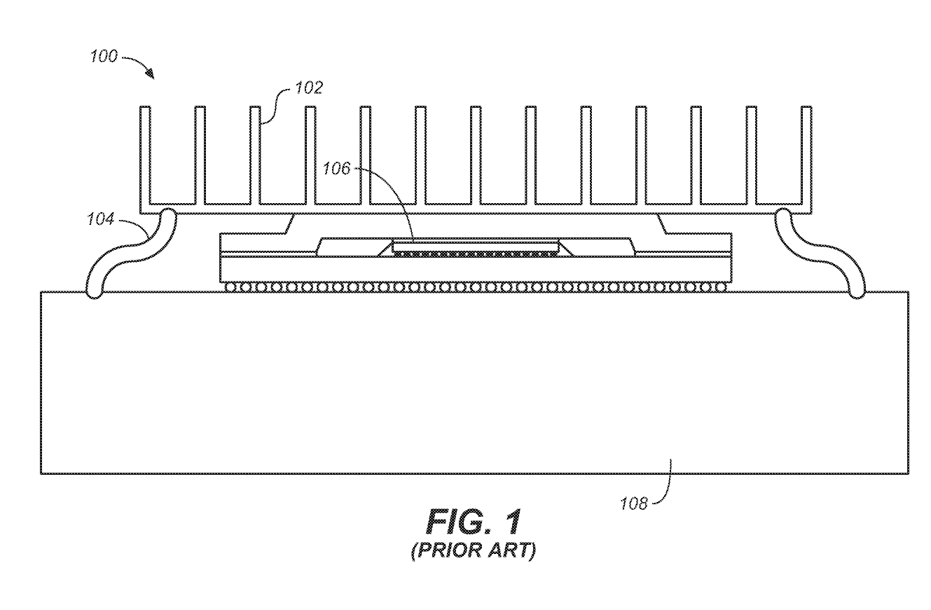

FIG. 1 illustrates side view of a shielded integrated circuit package 100 of the prior art with a heat spreader. Shown in FIG. 1 are a heat spreader 102, a grounding clip 104, an integrated circuit die 106, and a printed circuit board 108.

In FIG. 1, the integrated circuit die 106 is shielded from electromagnetic interference (EMI) from the top by the electrically conductive heat spreader 102. The grounding clips 104 shield the sides of the integrated circuit package and connect the heat spreader 102 to a ground plane on the printed circuit board 108.

A disadvantage of using the grounding clips 104 is that the sides of the integrated circuit package are exposed to EMI from the area of the printed circuit board 108 inside the grounding clips 104 around the integrated circuit package.

Another disadvantage of the grounding clips 104 is that the area of the printed circuit board 108 around the integrated circuit package is taken by the grounding clips 104 and may not be used for mounting components on the printed circuit board 108.

A preferable method of shielding the integrated circuit package from EMI is to connect the metal lid or heat spreader to ground through the integrated circuit package.

In one embodiment, an integrated circuit package for blocking electromagnetic interference includes a top layer formed in a package substrate. A first plurality of via groups is formed in the top layer surrounding an area on the top layer for an integrated circuit die. At least one lower layer is formed in the package substrate. A lower via group is formed in the lower layer below each of the first plurality of via groups, respectively. An electrical connection is formed in the lower layer between each lower via group and the first plurality of via groups, respectively. A ground connection is formed in the integrated circuit package for each lower via group to connect each lower via group to an electrical ground to block electromagnetic interference.

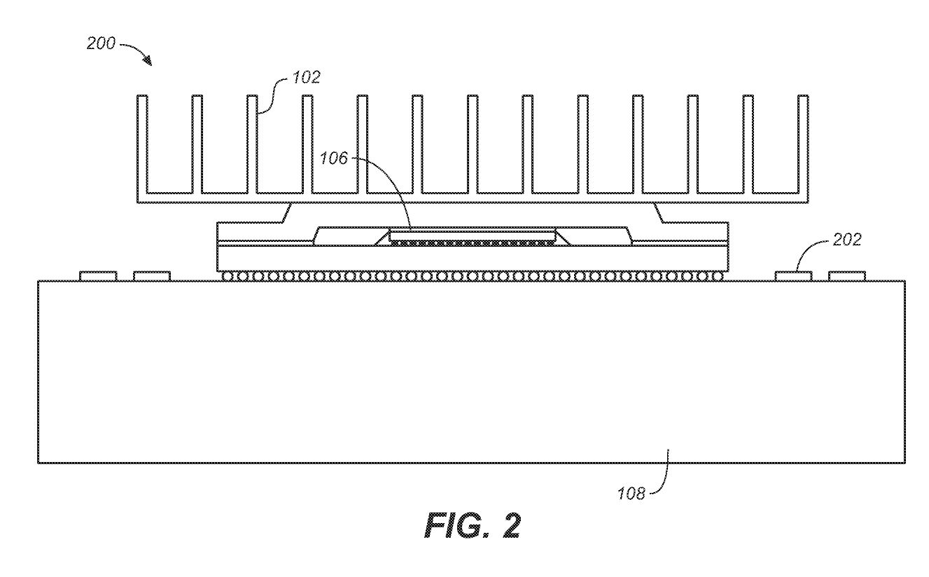

FIG. 2 illustrates a side view 200 of an integrated circuit package with internal side shielding. Shown in FIG. 2 are a heat spreader 102, an integrated circuit die 106, a printed circuit board 108, and printed circuit board components 202.

In FIG. 2, the heat spreader 102 is grounded to the printed circuit board 108 through the integrated circuit package. In this arrangement, the ground clips of FIG. 1 are not needed, advantageously freeing space on the printed circuit board 108 for the printed circuit board components 110. The printed circuit board components 110 may be, for example, capacitors, resistors, or inductors, as well as other electronic components.

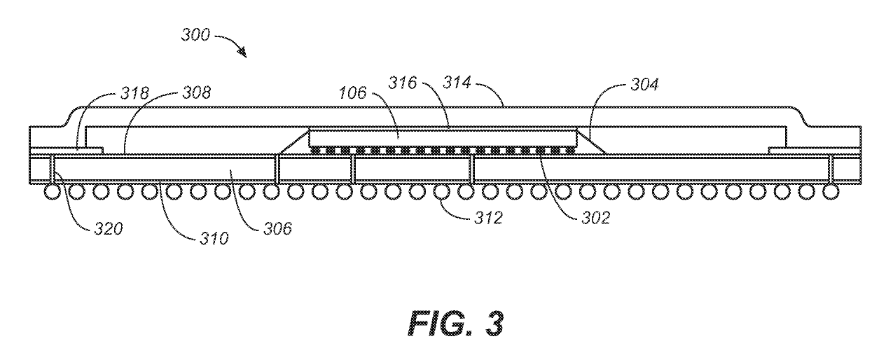

FIG. 3 illustrates a magnified view 300 of an integrated circuit package with internal side shielding and a metal lid. Shown in FIG. 3 are an integrated circuit die 106, solder bumps 302, an underfill 304, a package substrate 306, a top layer 308, a lower layer 310, solder balls 312, a package cover 314, a thermal compound 316, a lid seal 318, and a via group 320.

In FIG. 3, the integrated circuit die 106 makes electrical contact with the package substrate 306 via the solder bumps 302. The solder bumps 302 are sealed by the underfill 304. The package substrate 306 typically includes several electrically conductive layers, for example, the top layer 308 and the lower layer 310. Each of the electrically conductive layers is formed on an insulating layer to form a stack of alternating conductive and insulating layers. The top layer 308 is connected to each lower layer 310 by vias formed in the insulating layers between the conductive layers. Traces formed in the conductive layers of the package substrate 306 connect the vias from one conductive layer to the next. In this manner, the solder bumps 302 are connected to the solder balls 312 through the package substrate 306. The solder balls 312 connect the integrated circuit die 106 to a printed circuit board when the integrated circuit package is assembled on the printed circuit board. The integrated circuit die is protected by the package cover 314. The package cover 314 may be, for example, a metal lid with or without an added heat spreader structure such as fins to increase the thermal conductivity of the package cover 314. The package cover 314 is preferably made of an electrically and thermally conductive material, for example, copper or a copper-tin alloy. The thermal compound 316 conducts heat from the integrated circuit die 106 to the package cover 314.

The following features are added to the previously known features of the integrated circuit package in FIG. 3 to ground the package cover 314 through the package substrate 306. In one embodiment, the thermal compound 316 may a thermally conductive material typically used to increase thermal conductivity between the lid and the die. In another embodiment, the thermal compound 316 may a material that is not only thermally conductive, but also electrically conductive, such as an electrically conductive epoxy adhesive. The thermal compound 316 fills the void between the package cover 314 and the integrated circuit die 106.

The lid seal 318 is made of an electrically conductive material, for example, an electrically conductive epoxy adhesive. The lid seal 318 electrically connects the package cover 314 to the top layer 308 of the integrated circuit package. The via groups 320 electrically connect the package cover 314 through the package substrate 306 to the solder balls 312 from the top layer 308 to each lower layer 310 to complete the electrical connection between the package cover 314 and a ground on the printed circuit board 202 in FIG. 2 or a ground plane layer in the package substrate 306.

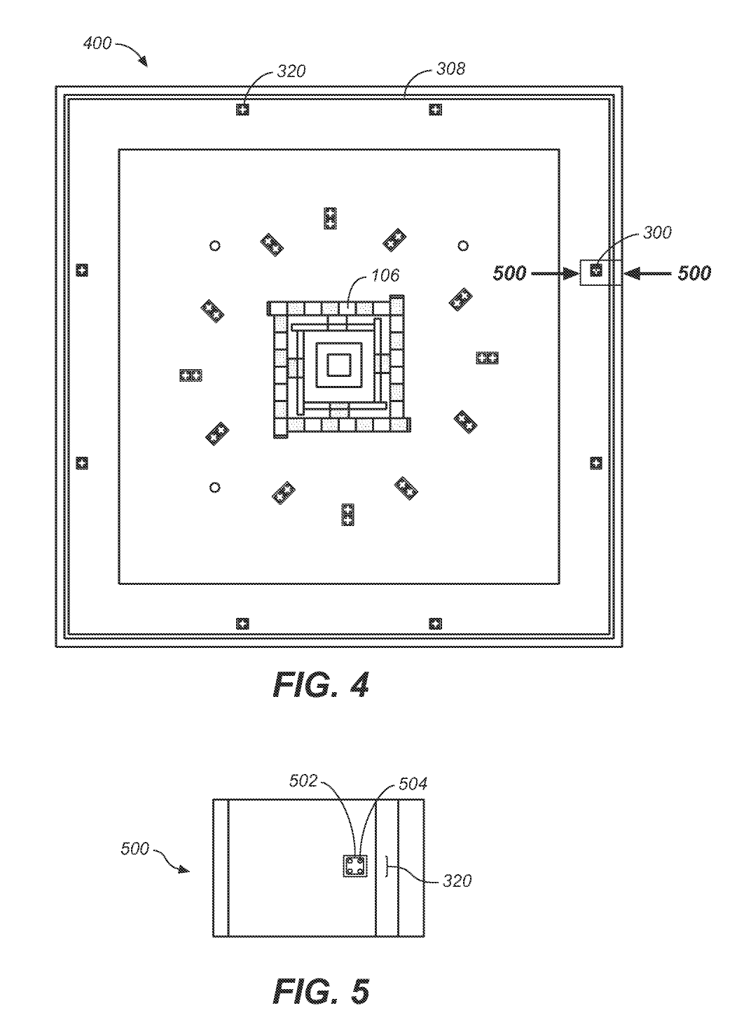

FIG. 4 illustrates a top view 400 of the top layer in the package substrate of FIG. 3. Shown in FIG. 4 are an integrated circuit die 106, a top layer 308, and via groups 320.

In FIG. 4, the integrated circuit die 106 is mounted on the top layer 308 of the package substrate as described above with reference to FIG. 3. Package substrates for flip-chip and wire-bond integrated circuits may be used to practice various embodiments within the scope of the appended claims. One or more via groups 320 are formed on each side of the integrated circuit die 106. The via groups 320 are electrically connected to the package cover 314 in FIG. 3 by applying the thermal compound 316 between each of the via groups 320 and the package cover 314. As a result, the integrated circuit die 106 is surrounded by ground conductors inside the area of the package substrate that enclose the integrated circuit die 106 from top to bottom, advantageously forming a ground shield that blocks EMI radiation at a distance of, for example, 15 millimeters or less from the integrated circuit die 106. In contrast to the via groups 320, the grounding clips 104 in FIG. 1 form a ground shield completely outside the integrated circuit package, which may not provide adequate EMI shielding at the sides of integrated circuit die 106.

FIG. 5 illustrates a magnified view 500 of a via group formed in the top layer of the package substrate in FIG. 4. Shown in FIG. 5 are a via group 320, a contact pad 502, and vias 504.

In FIG. 5, the contact pad 502 is formed in the top layer 308 of the package substrate according to well-known techniques. The area of the contact pad 502 is selected to enclose the vias 504 and to provide a surface for applying the electrically conductive thermal compound 316. In this example, the via group 320 includes four vias 504; however, the number of vias 504 in each of the via groups 320 may be selected to suit various applications within the scope of the appended claims. The vias 504 connect the top layer 308 to each lower layer 310 of the package substrate. An example of a via group for each layer of a ten-layer package substrate is described as follows.

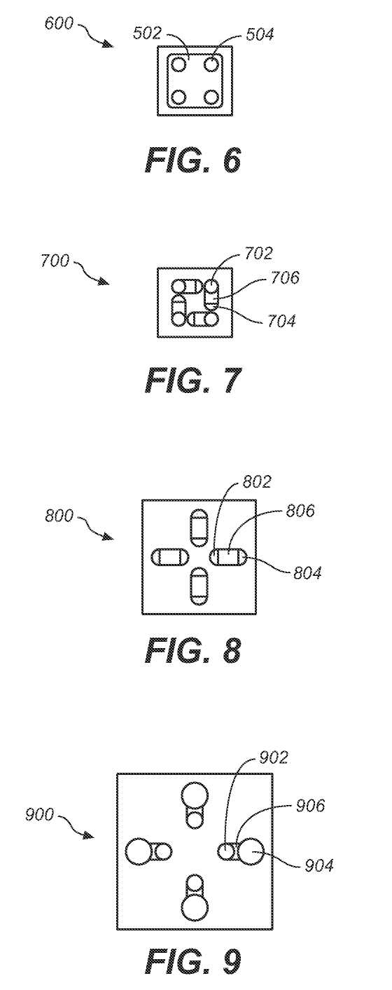

FIG. 6 illustrates a magnified view 600 of a via group formed on the top layer of a ten-layer package substrate. Shown in FIG. 6 are a contact pad 502 and vias 504.

In FIG. 6, the vias 504 connect the top layer to the second layer.

FIG. 7 illustrates a magnified view 700 of connections formed in the second layer between the via group in the top layer and the via group in the third layer of the package substrate of FIG. 6. Shown in FIG. 7 are second layer vias 702, third layer vias 704, and trace connections 706.

In FIG. 7, the second layer vias 702 are connected to the third layer vias 704 by the trace connections 706. The trace connections 706 are routed so that the via groups in the top and third layers have the same area.

FIG. 8 illustrates a magnified view 800 of connections formed in the third layer between the via group in the second layer and the via group in the fourth layer of the package substrate of FIG. 7. Shown in FIG. 8 are third layer vias 802, fourth layer vias 804, and trace connections 806.

In FIG. 8, the third layer vias 802 are connected to the fourth layer vias 804 by the trace connections 806. The trace connections 806 are routed so that the via group in the fourth layer has a larger area than the via group in the third layer in anticipation of a larger via size in the next layer.

FIG. 9 illustrates a magnified view 900 of connections formed in the fourth layer between the via group in the third layer and the via group in the fifth layer of the package substrate of FIG. 8. Shown in FIG. 9 are fourth layer vias 902, fifth layer vias 904, and trace connections 906.

In FIG. 9, the fourth layer vias 902 are connected to the fifth layer vias 904 by the trace connections 906. The trace connections 906 are routed so that the via group in the fifth layer has a larger area than the via group in the fourth layer to accommodate the larger via size in the fifth layer, which may be, for example, a power or ground plane layer. In one embodiment, each via group in one of the lower layers is connected to the ground plane layer of the integrated circuit package. In another embodiment, each via group in one of the lower layers is connected to a ground separate from the integrated circuit package ground by the solder balls formed on the package substrate, for example, to isolate noise injection from electromagnetic interference.

The fifth layer vias may be connected to an identical via pattern in the sixth layer. The sixth layer vias may be connected to the seventh layer vias by reversing the order of the layers shown in FIG. 9. Likewise, the seventh layer vias may be connected to the eighth layer vias by reversing the order of the layers shown in FIG. 8, the eighth layer vias may be connected to the ninth layer vias by reversing the order of the layers shown in FIG. 7, and the ninth layer vias may be connected to the tenth layer vias as shown in FIG. 6. The tenth layer is connected to a selected number of the solder balls 312 in FIG. 3, for example, one solder ball 312 for each via group 320. The solder balls 312 connect the via groups to the printed circuit board ground according to well-known techniques. The number of layers may be other than 10, for example, package substrates having 2, 3, 4, 5, 6, 7, and 8 layers may be used to practice other embodiments within the scope of the appended claims. Also, the package substrate may be made of ceramic, organic, or other materials used to make package substrates. The integrated circuit package design described above advantageously applies to any chip frequency.

In another embodiment, a method of making an integrated circuit package includes steps of forming a top layer in a package substrate. A first plurality of via groups is formed in the top layer surrounding an area on the top layer for an integrated circuit die. At least one lower layer is formed in the package substrate. A lower via group is formed in the lower layer below each of the first plurality of via groups, respectively. An electrical connection is formed in the lower layer between each lower via group and the first plurality of via groups, respectively. A ground connection is formed in the integrated circuit package for each lower via group to connect each lower via group to an electrical ground to block electromagnetic interference.

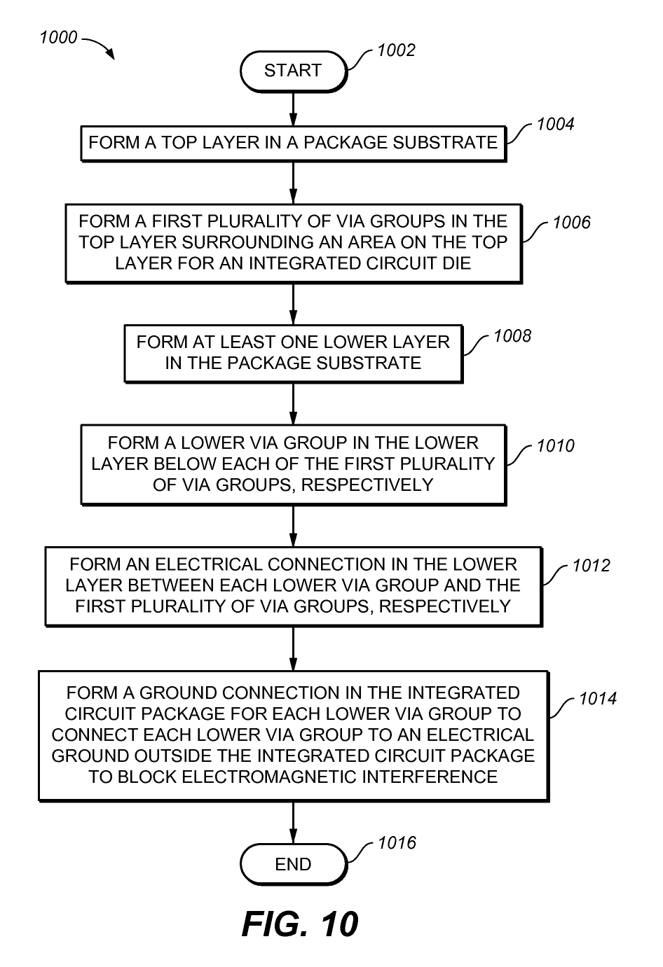

FIG. 10 illustrates a flow chart for making an integrated circuit package with a ground shield grounded inside the integrated circuit package.

Step 1002 is the entry point of the flow chart 1000.

In step 1004, a top layer is formed in a package substrate of an integrated circuit according to well-known techniques.

In step 1006, a first plurality of via groups is formed in the top layer surrounding an area on the top layer for an integrated circuit die. The spacing between adjacent via groups is preferably made less than one-tenth of the wavelength of the highest EMI signal to effectively block EMI radiation. An electrically conductive package cover having an area that encloses the first plurality of via groups may be connected to each of the first plurality of via groups, for example, by a conductive epoxy as described with reference to FIG. 3. The package cover may be, for example, a metal lid or a metal lid and a heat spreader as shown in FIG. 3.

In step 1008, at least one lower layer is formed in the package substrate.

In step 1010, a lower via group is formed in the lower layer below each of the first plurality of via groups, respectively;

In step 1012, an electrical connection is formed in the lower layer between each lower via group and the first plurality of via groups, respectively. The electrical connections may be, for example, traces formed in the lower layer from the vias in a via group in the layer above the lower layer to the vias in a via group in the layer below the lower layer as shown in FIGS. 7, 8, and 9.

In step 1014, a ground connection is formed in the integrated circuit package for each lower via group to connect each lower via group to an electrical ground outside the integrated circuit package to block electromagnetic interference. The ground connection may be made, for example, by connecting each lower via group to a solder ball on the lower layer of the package substrate.

Step 1016 is the exit point of the flow chart 1000.

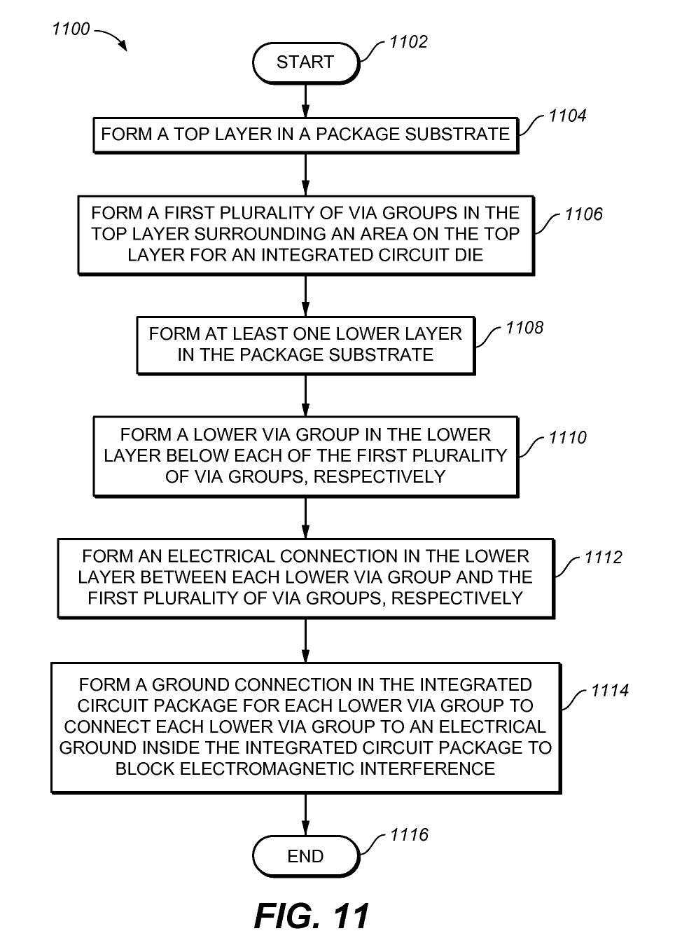

FIG. 11 illustrates a flow chart for making an integrated circuit package with a ground shield grounded inside the integrated circuit package.

Step 1102 is the entry point of the flow chart 1000.

In step 1104, a top layer is formed on a package substrate of an integrated circuit according to well-known techniques.

In step 1106, a first plurality of via groups is formed in the top layer surrounding an area on the top layer for an integrated circuit die. The spacing between adjacent via groups is preferably made less than one-tenth of the wavelength of the highest EMI signal to effectively block EMI radiation. An electrically conductive package cover having an area that encloses the first plurality of via groups may be connected to each of the first plurality of via groups, for example, by a conductive epoxy as described with reference to FIG. 3.

In step 1108, at least one lower layer is formed on the package substrate.

In step 1110, a lower via group is formed in the lower layer below each of the first plurality of via groups, respectively;

In step 1112, an electrical connection is formed on the lower layer between each lower via group and the first plurality of via groups, respectively. The electrical connections may be, for example, traces formed in the lower layer from the vias in a via group in the layer above the lower layer to the vias in a via group in the layer below the lower layer as shown in FIGS. 7, 8, and 9.

In step 1114, a ground connection is formed in the integrated circuit package for each lower via group to connect each lower via group to an electrical ground inside the integrated circuit package to block electromagnetic interference. The ground connection may be made, for example, by connecting each lower via group to a ground plane layer in the package substrate.

Step 1116 is the exit point of the flow chart 1100.

Although the method illustrated by the flowchart description above is described and shown with reference to specific steps performed in a specific order, these steps may be combined, sub-divided, or reordered without departing from the scope of the claims. Unless specifically indicated herein, the order and grouping of steps is not a limitation of the present invention.

While the invention herein disclosed has been described by means of specific embodiments and applications thereof, numerous modifications and variations could be made thereto by those skilled in the art without departing from the scope of the invention set forth in the following claims.

The specific embodiments and applications thereof described above are for illustrative purposes only and do not preclude modifications and variations that may be made within the scope of the following claims.

What is claimed is:

1. An integrated circuit package comprising:
a top layer formed in a package substrate;
a first plurality of via groups formed in the top layer surrounding an area on the top layer for an integrated circuit die;
at least one lower layer formed in the package substrate;
a lower via group formed in the lower layer below each of the first plurality of via groups, respectively;
an electrical connection formed in the lower layer between each lower via group and the first plurality of via groups, respectively; and
a ground connection formed in the integrated circuit package for each lower via group to connect each lower via group to an electrical ground to block electromagnetic interference.

2. The integrated circuit package of claim 1 further comprising an electrically conductive package cover having an area that encloses the first plurality of via groups and is electrically connected to each of the first plurality of via groups.

3. The integrated circuit package of claim 2 further comprising an electrically conductive adhesive connecting the package cover to each of the first plurality of via groups.

4. The integrated circuit package of claim 1 further comprising the electrical ground inside the integrated circuit package.

5. The integrated circuit package of claim 1 further comprising the electrical ground outside the integrated circuit package.

6. The integrated circuit package of claim 2, the package cover comprising a metal lid.

7. The integrated circuit package of claim 2, the package cover comprising a heat spreader.

8. The integrated circuit package of claim 7 further comprising a printed circuit board, the printed circuit board comprising a surface on which the integrated circuit package is mounted and an electrical component connected to the surface inside an area enclosed by the heat spreader.

9. The integrated circuit package of claim 8, the electrical component comprising a capacitor, a resistor, or an inductor.

10. A method of making an integrated circuit package comprising steps of:
forming a top layer in a package substrate;
forming a first plurality of via groups in the top layer surrounding an area on the top layer for an integrated circuit die;
forming at least one lower layer in the package substrate;
forming a lower via group in the lower layer below each of the first plurality of via groups, respectively;
forming an electrical connection in the lower layer between each lower via group and the first plurality of via groups, respectively; and
forming a ground connection in the integrated circuit package for each lower via group to connect each lower via group to an electrical ground to block electromagnetic interference.

11. The method of claim 10 further comprising a step of connecting an electrically conductive package cover having an area that encloses the first plurality of via groups to each of the first plurality of via groups.

12. The method of claim 11 further comprising a step of connecting the package cover to each of the first plurality of via groups with an electrically conductive adhesive.

13. The method of claim 10 further comprising a step of connecting each lower via group to an electrical ground inside the integrated circuit package.

14. The method of claim 10 further comprising a step of connecting each lower via group to an electrical ground outside the integrated circuit package.

15. The method of claim 11 further comprising a step of providing the package cover comprising a metal lid.

16. The method of claim 11 further comprising a step of providing the package cover comprising a heat spreader.

17. The method of claim 16 further comprising a step of mounting the integrated circuit package on a surface of a printed circuit board and connecting an electrical component to the surface inside an area enclosed by the heat spreader.

18. The method of claim 17 further comprising a step of providing the electrical component comprising a capacitor, a resistor, or an inductor.

19. The integrated circuit package of claim 1, the integrated circuit package being included in a flip chip integrated circuit package or a wire bond integrated circuit package.

20. The integrated circuit package of claim 1, the package substrate comprising 2, 3, 4, 5, 6, 7, or 8 layers.

21. The integrated circuit package of claim 1, the package substrate comprising a ceramic or an organic material.
